(19) United States
(12) Patent Application Publication
(10) Pub. No.: US 2026/0182441 A1
(43) Pub. Date: Jun. 25, 2026

(54) SEMICONDUCTOR DEVICE ASSEMBLIES WITH BOND LINES INCLUDING ALUMINUM NITRIDE GAP FILL MATERIAL AND METHODS OF FORMING THE SAME

(71) Applicant: Micron Technology, Inc., Boise, ID (US)

(72) Inventors: Wei Zhou, Boise, ID (US); Vladimir Noveski, San Diego, CA (US); Amy R. Griffin, Boise, ID (US)

(21) Appl. No.: 19/370,595

(22) Filed: Oct. 27, 2025

Related U.S. Application Data
(60) Provisional application No. 63/737,471, filed on Dec. 20, 2024.

(51) Int. Cl. H01L 23/31; H01L 21/56; H01L 23/00; H01L 25/18; H10B 80/00; H10D 80/30

(52) U.S. Cl. CPC H10W 74/121; H10B 80/00; H10D 80/30; H10W 74/01; H10W 90/00; H10W 74/15; H10W 90/26; H10W 90/722; H10W 90/724; H10W 90/732; H10W 90/734

(57) ABSTRACT

A semiconductor device assembly is provided. The assembly includes a first semiconductor device having an upper surface, a second semiconductor device carried by the first semiconductor device and having a lower surface facing the upper surface of the first semiconductor device, a plurality of interconnects extending from the upper surface to the lower surface and across a bond line having a thickness, and an aluminum nitride material disposed between the upper surface and the lower surface and surrounding each of the plurality of interconnects.

### CROSS-REFERENCE TO RELATED APPLICATION(S)

The present application claims priority to U.S. Provisional Patent Application No. 63/737,471, filed Dec. 20, 2024, the disclosure of which is incorporated herein by reference in its entirety.

### TECHNICAL FIELD

The present disclosure generally relates to semiconductor device assemblies, and more particularly relates to semiconductor device assemblies with bond lines including aluminum nitride (AlN) gap fill material and methods of forming the same.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

FIG. 1 is a simplified schematic cross-sectional view of a semiconductor device assembly in accordance with some embodiments of the present technology.

FIG. 2 is a simplified schematic cross-sectional view of a semiconductor device assembly in accordance with some embodiments of the present technology.

FIG. 3 is a simplified schematic cross-sectional view of a semiconductor device assembly in accordance with some embodiments of the present technology.

FIG. 4 is a simplified schematic cross-sectional view of a semiconductor device assembly in accordance with some embodiments of the present technology.

FIG. 5 is a flow chart illustrating a method of making a semiconductor device assembly in accordance with an embodiment of the present technology.

FIG. 6 is a schematic view showing a system that includes a semiconductor device assembly configured in accordance with an embodiment of the present technology.

### DETAILED DESCRIPTION

Some packaged semiconductor devices include multiple devices arranged in a die stack, with each device electrically coupled to an adjacent device by a plurality of interconnects, such as pads, pillars, posts, or other electrically conductive structures joined by a solder joint. The vertical extent of the interconnects defines a bond line height—the space between the lower surface of one device and the upper surface of another over which it is stacked. The remaining space of the bond line that is not occupied by interconnects may be occupied by a gap fill material that provides mechanical stability, electrical isolation, and environmental protection (e.g., sealing the interconnects against corrosive moisture or possibly conductive contaminants). This gap fill material may include non-conductive film (NCF), molded underfill (MUF), capillary underfill (CUF) or even resinous encapsulating mold material. A drawback of these materials is their relatively low thermal conductivity-on the order of around 1 W/mK. For higher performance semiconductor devices that generate waste heat during operation and may rely upon the vertical transportation of thermal energy through the vertical die stack to extract heat from the assembly, such low thermal conductivity poses a packaging challenge.

To address these drawbacks and others, various embodiments of the present application provide semiconductor device assemblies with highly thermally conductive gap fill material, such as aluminum nitride (AlN), between devices in a stack. AlN enjoys a thermal conductivity about two orders higher than the aforementioned gap fill materials (e.g., between about 150 and 250 W/mK), and provides a dramatic improvement in the vertical conduction of thermal energy through a device stack. The AlN material may fill all of the space between facing devices not otherwise occupied by interconnects, or may be one or more of several layers of material in the region. The AlN material may be introduced between the devices prior to or subsequent to their stacking, and may be formed prior to or subsequent to the formation of interconnects one or both of the facing devices.

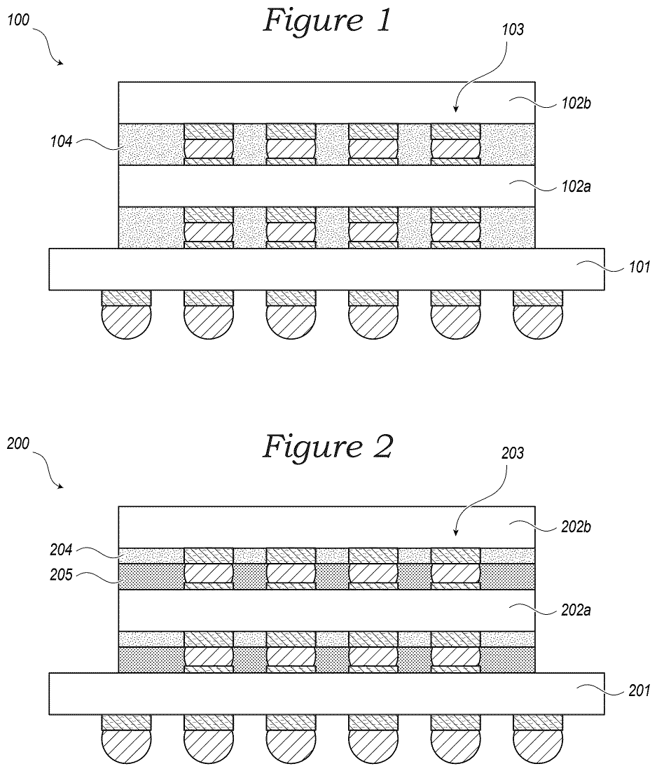

FIG. 1 is a simplified schematic cross-sectional view of a semiconductor device assembly 100 in accordance with embodiments of the present technology. As can be seen with reference to FIG. 1, assembly 100 can include a first semiconductor device 101 over which is mounted one or more additional semiconductor devices, such as semiconductor device 102a and 102b. First semiconductor device 101 can further include package-level contact pads and/or a ball grid array (BGA) for providing external connectivity (e.g., via solder balls) to the assembly 100 (e.g., power, ground, and I/O signals) through traces, lines, vias, and other electrical connection structures (not illustrated).

Between the semiconductor devices in the assembly, an aluminum nitride (AlN) gap fill material 104 can be provided, laterally surrounding the interconnects 103 between the devices and extending from the facing surface of one device to the facing surface of an adjacent device (e.g., from the lower surface of an overlying device to the upper surface of a device carrying the former). The aluminum nitride material may be introduced into the bond line by one or more of a variety of processes, including atomic layer deposition (ALD), physical vapor deposition (PVD), chemical vapor deposition (CVD), and/or sputtering. The aluminum nitride material between two facing devices may be a monolithic layer, provided in a single process, or provided in multiple steps (e.g., with a first portion provided on the lower surface of the upper die and a second portion provided on the upper surface of the lower die prior to stacking the dies).

In accordance with one aspect of the present disclosure, disposing the aluminum nitride material may involve a low temperature process occurring at less than 200° C. (e.g., so as not to reflow the solder of the interconnects 103).

Although in the foregoing example embodiment semiconductor device assemblies have been illustrated and described as including an aluminum nitride material that completely occupies the space between facing devices not otherwise occupied by interconnects, in other embodiments assemblies can be provided with additional materials between facing dies in a stack. For example, FIG. 2 is a simplified schematic cross-sectional view of a semiconductor device assembly 200 in accordance with embodiments of the present technology in which a bond line includes both an aluminum nitride material and another dielectric material 205.

As can be seen with reference to FIG. 2, assembly 200 can include a first semiconductor device 201 over which is mounted one or more additional semiconductor devices, such as semiconductor device 202a and 202b. First semiconductor device 201 can further include package-level contact pads and/or a ball grid array (BGA) for providing external connectivity (e.g., via solder balls) to the assembly 200 (e.g., power, ground, and I/O signals) through traces, lines, vias, and other electrical connection structures (not illustrated). Between the semiconductor devices in the assembly, an aluminum nitride (AlN) gap fill material 204 can be provided (e.g., on the lower surface of each device overlying a bond line), laterally surrounding the interconnects 203 between the devices and extending to a height/thickness that is less than the thickness of the bond line (e.g., from the lower surface of an overlying device to the thickness of an interconnect component such as a pad or pillar formed at the lower surface). In such an arrangement, the remaining height of the bond line may be occupied by another dielectric material 205 (e.g., such as non-conductive film (NCF), molded underfill (MUF), capillary underfill (CUF) or even resinous encapsulating mold material).

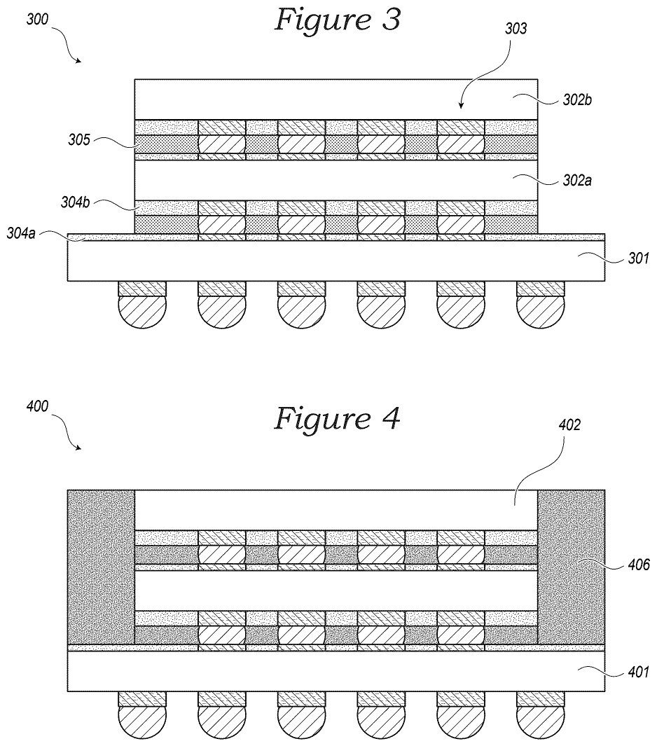

Although in the foregoing example embodiment semiconductor device assemblies have been illustrated and described as including a single aluminum nitride material layer disposed in each bond line, in other embodiments assemblies can be provided with additional aluminum nitride material layers between facing dies in a stack. For example, FIG. 3 is a simplified schematic cross-sectional view of a semiconductor device assembly 300 in accordance with embodiments of the present technology in which the bond lines between facing devices include multiple aluminum nitride material layers 304a and 304b as well as another dielectric material 305.

As can be seen with reference to FIG. 3, assembly 300 can include a first semiconductor device 301 over which is mounted one or more additional semiconductor devices, such as semiconductor device 302a and 302b. First semiconductor device 301 can further include package-level contact pads and/or a ball grid array (BGA) for providing external connectivity (e.g., via solder balls) to the assembly 300 (e.g., power, ground, and I/O signals) through traces, lines, vias, and other electrical connection structures (not illustrated). Between the semiconductor devices in the assembly, layers of an aluminum nitride (AlN) gap fill material can be provided (e.g., with one layer 304b on the lower surface of each device overlying a bond line and another layer 304a on the upper surface of each device overlaid by another facing device), laterally surrounding the interconnects 303 between the devices and each extending to a height/thickness that is less than the thickness of the bond line (e.g., from the surface of a corresponding device to the thickness of an interconnect component such as a pad or pillar formed at the surface). In such an arrangement, the remaining height of the bond line may be occupied by another dielectric material 305 (e.g., such as non-conductive film (NCF), molded underfill (MUF), capillary underfill (CUF) or even resinous encapsulating mold material).

In accordance with another aspect of the present disclosure, an assembly may further include an encapsulating mold material that surrounds at least the sidewalls of at least some of the devices in an assembly. For example, FIG. 4 is a simplified schematic cross-sectional view of a semiconductor device assembly 400 in accordance with embodiments of the present technology in which the an encapsulating mold material 406 surrounds the sidewalls of a stack of semiconductor devices (e.g., memory dies) carried by a larger semiconductor device 401 (e.g., a logic die such as a memory controller, an interface die, or a processor). In accordance with one aspect of the present disclosure, the mold material 406 may further occupy a portion of the bond lines between facing devices in the stack (e.g., adjacent the aluminum nitride material layer(s) disposed in the bond lines).

Although in the foregoing example embodiment semiconductor device assemblies have been illustrated and described as including a single first semiconductor device (with a first footprint) carrying two second semiconductor devices (with a second smaller footprint), in other embodiments other package arrangements may include a greater or lesser number of dies of greater or fewer sizes, mutatis mutandis. Moreover, although in the foregoing example embodiment semiconductor device assemblies have been illustrated and described with multiple bond lines all of a similar thickness, in other embodiments bond lines in an assembly may have varying heights. For example, bond lines on the order of 10 μm (e.g., between about 5 and 50 μm) may be disposed between some pairs of facing dies, and bond lines on the order of 1 μm (e.g., between about 0.5 and 5 μm) may be disposed between other pairs.

In accordance with one aspect of the present disclosure, the semiconductor devices illustrated in the assemblies of FIGS. 1-4 could be memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single assembly, the semiconductor devices could be memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, etc.), or a mix of logic and memory dies (e.g., a memory controller die and a memory die controlled thereby).

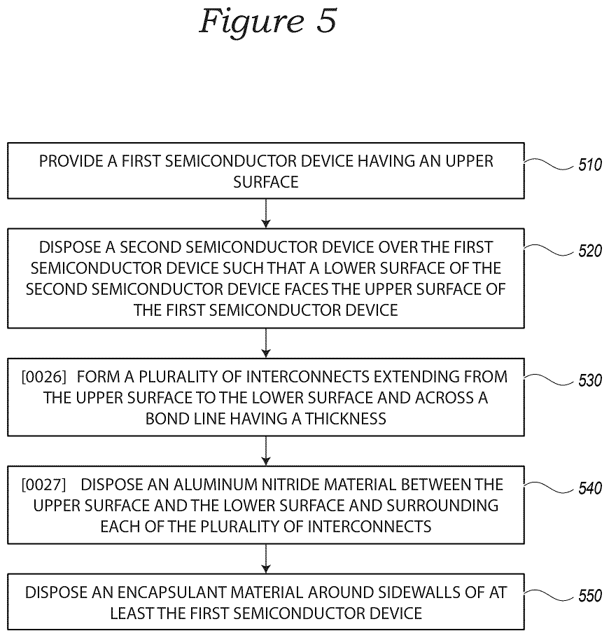

FIG. 5 is a flow chart illustrating a method of making a semiconductor device assembly. The method may include providing a first semiconductor device having an upper surface (box 510) and disposing a second semiconductor device over the first semiconductor device such that a lower surface of the second semiconductor device faces the upper surface of the first semiconductor device (box 520). The method may further include forming a plurality of interconnects extending from the upper surface to the lower surface and across a bond line having a thickness (box 530) and disposing an aluminum nitride material between the upper surface and the lower surface and surrounding each of the plurality of interconnects (box 540). The method may further include disposing an encapsulant material around sidewalls of at least the first semiconductor device (box 550).

In accordance with one aspect of the present disclosure, disposing an aluminum nitride material (as in box 540) may comprise at least one of atomic layer deposition (ALD), physical vapor deposition (PVD), chemical vapor deposition (CVD), and sputtering. The disposing of the aluminum nitride material may be performed subsequent to disposing the second semiconductor device over the first semiconductor device in some embodiments, and prior to disposing the second semiconductor device over the first semiconductor device in other embodiments. The disposing of the aluminum nitride material may be performed prior to forming the plurality of interconnects in some embodiments, and subsequent to forming the plurality of interconnects in other embodiments.

In accordance with one aspect of the present disclosure, the aluminum nitride material may be disposed with a height substantially equal to the thickness of the bond line; in accordance with yet another aspect, the aluminum nitride material may be disposed with a height less than the thickness of the bond line, and the method may further include disposing a dielectric material adjacent the aluminum nitride material between the upper surface of the first semiconductor device and the lower surface of the second semiconductor device.

In accordance with one aspect of the present disclosure (e.g., as when the interconnects comprise a solder material), disposing the aluminum nitride material may involve a low temperature process occurring at less than 200° C. (e.g., so as not to reflow the solder).

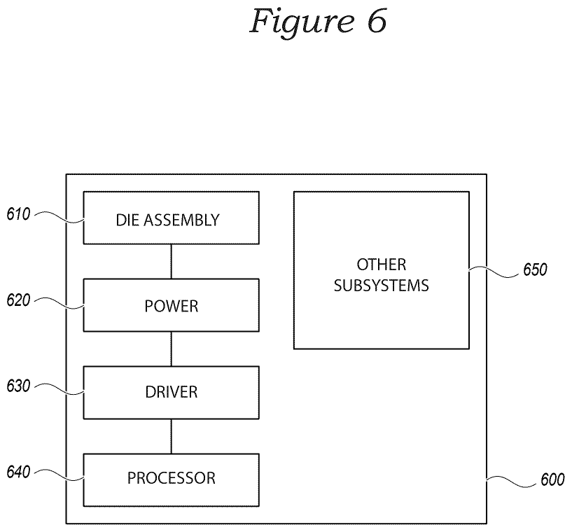

Any one of the semiconductor devices and semiconductor device assemblies described above with reference to FIGS. 1-5 can be incorporated into any of a myriad of larger and/or more complex systems, a representative example of which is system 600 shown schematically in FIG. 6. The system 600 can include a semiconductor device assembly (e.g., or a discrete semiconductor device) 602, a power source 604, a driver 606, a processor 608, and/or other subsystems or components 610. The semiconductor device assembly 602 can include features generally similar to those of the semiconductor devices described above with reference to FIGS. 1-15 The resulting system 600 can perform any of a wide variety of functions, such as memory storage, data processing, and/or other suitable functions. Accordingly, representative systems 600 can include, without limitation, hand-held devices (e.g., mobile phones, tablets, digital readers, and digital audio players), computers, vehicles, appliances and other products. Components of the system 600 may be housed in a single unit or distributed over multiple, interconnected units (e.g., through a communications network). The components of the system 600 can also include remote devices and any of a wide variety of computer readable media.

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

In other embodiments, the term “substrate” can refer to a package-level substrate upon which other semiconductor devices are carried, such as a printed circuit board (PCB), an interposer, or another semiconductor device.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device assembly, comprising:
a first semiconductor device having an upper surface;
a second semiconductor device carried by the first semiconductor device and having a lower surface facing the upper surface of the first semiconductor device;
a plurality of interconnects extending from the upper surface to the lower surface and across a bond line having a thickness; and
an aluminum nitride material disposed between the upper surface and the lower surface and surrounding each of the plurality of interconnects.

2. The semiconductor device assembly of claim 1, wherein the aluminum nitride material has a height substantially equal to the thickness of the bond line.

3. The semiconductor device assembly of claim 1, wherein the aluminum nitride material has a height less than the thickness of the bond line, and further comprising a dielectric material adjacent the aluminum nitride material between the upper surface and the lower surface.

4. The semiconductor device assembly of claim 1, wherein the plurality of interconnects comprise solder.

5. The semiconductor device assembly of claim 1, wherein the first semiconductor device is a logic die and the second semiconductor device is a memory die.

6. The semiconductor device assembly of claim 1, further comprising an encapsulant material surrounding sidewalls of at least the first semiconductor device.

7. The semiconductor device assembly of claim 1, further comprising a third semiconductor device carried by the second semiconductor device and an additional region of the aluminum nitride material disposed between the third semiconductor device and the second semiconductor device.

8. A method of making a semiconductor device assembly, comprising:
providing a first semiconductor device having an upper surface;
disposing a second semiconductor device over the first semiconductor device such that a lower surface of the second semiconductor device faces the upper surface of the first semiconductor device;
forming a plurality of interconnects extending from the upper surface to the lower surface and across a bond line having a thickness; and
disposing an aluminum nitride material between the upper surface and the lower surface and surrounding each of the plurality of interconnects.

9. The method of claim 8, wherein disposing the aluminum nitride material comprises at least one of atomic layer deposition (ALD), physical vapor deposition (PVD), chemical vapor deposition (CVD), and sputtering.

10. The method of claim 8, wherein disposing the aluminum nitride material is performed subsequent to disposing the second semiconductor device over the first semiconductor device.

11. The method of claim 8, wherein disposing the aluminum nitride material is performed prior to disposing the second semiconductor device over the first semiconductor device.

12. The method of claim 8, wherein disposing the aluminum nitride material is performed prior to forming the plurality of interconnects.

13. The method of claim 8, wherein disposing the aluminum nitride material is performed subsequent to forming the plurality of interconnects.

14. The method of claim 8, wherein the aluminum nitride material has a height substantially equal to the thickness of the bond line.

15. The method of claim 8, wherein the aluminum nitride material has a height less than the thickness of the bond line, and further comprising disposing a dielectric material adjacent the aluminum nitride material between the upper surface and the lower surface.

16. The method of claim 8, wherein the plurality of interconnects comprise solder.

17. The method of claim 16, wherein disposing the aluminum nitride material comprises a low temperature process occurring at less than 200° C.

18. The method of claim 8, wherein the first semiconductor device is a logic die and the second semiconductor device is a memory die.

19. The method of claim 8, further comprising disposing an encapsulant material around sidewalls of at least the first semiconductor device.

20. The method of claim 8, further comprising disposing a third semiconductor device over the second semiconductor device and disposing an additional region of the aluminum nitride material between the third semiconductor device and the second semiconductor device.
